(19) United States
(12) Patent Application Publication
(10) Pub. No.: US 2020/0111802 A1
(43) Pub. Date: Apr. 9, 2020

(54) METHOD OF PREVENTING CHARGE LOSS FROM A FLOATING GATE

(71) Applicant: UNITED MICROELECTRONICS CORP., Hsin-Chu City (TW)

(72) Inventors: Nan-Yuan Huang, Tainan City (TW); Cheng-Lin Peng, Tainan City (TW); Lung-En Kuo, Tainan City (TW); Li-Chieh Hsu, Taichung City (TW)

(21) Appl. No.: 16/152,368

(22) Filed: Oct. 4, 2018

(51) Int. Cl. H01L 27/11534; H01L 21/32; H01L 21/3105; H01L 27/11519; H01L 27/11521

(52) U.S. Cl. CPC H01L 27/11534; H01L 21/32; H01L 27/11521; H01L 27/11519; H01L 21/31053

(57) ABSTRACT

A method of preventing charge loss from a floating gate includes providing a substrate comprising a memory cell region and a logic region, wherein a floating gate is disposed in the memory cell region and a gate structure is disposed within the logic region, a first hard mask covers the floating gate and a second hard mask covers the first hard mask. A planarization process is performed to remove entirely the second hard mask and expose the first hard mask. Later, a third hard mask is formed to cover the first hard mask, the gate structure and the substrate, wherein the third hard mask prevents charges in the floating gate from flowing to the first hard mask. Finally, the third hard mask within the logic region is removed and the third hard mask remains within the memory region.

### BACKGROUND OF THE INVENTION

### 1. Field of the Invention

The present invention relates to a method of preventing charge loss in a floating gate, and more particularly to a method of replacing a hard mask on a floating gate to prevent charge loss in the floating gate.

### 2. Description of the Prior Art

Nonvolatile memory cell arrays such as EPROMs, FLASH EPROMs and EEPROMs have gained widespread acceptance in the industry. Nonvolatile memory cells do not require periodic refresh pulses, unlike DRAM cells.

Flash memory devices have developed into a popular source of non-volatile memory for a wide range of electronic applications. Common uses for flash memory include personal computers, personal digital assistants (PDAs), digital cameras, and cellular telephones. Program code and system data such as a basic input/output system (BIOS) are typically stored in flash memory devices for use in personal computer systems.

During a standard programming operation of a flash memory cell, a selected word line coupled to the selected memory cell to be programmed is biased with a series of incrementing voltage programming pulses that start at an initial voltage that is greater than a predetermined programming voltage. The programming pulse increase in charge level, thereby increasing the cell's threshold voltage Vₜ, on a floating gate of the memory cell.

It has been observed, however, that there are delays in charging and discharging of a flash because the electrons in the floating gate are trapped by the other material layers.

### SUMMARY OF THE INVENTION

According to a preferred embodiment of the present invention, a method of preventing charge loss from a floating gate, includes providing a substrate comprising a memory cell region and a logic region, wherein a floating gate is disposed in the memory cell region and a gate structure is disposed within the logic region, a first hard mask covers the floating gate and a second hard mask covers the first hard mask. A planarization process is performed to remove entirely the second hard mask and expose the first hard mask. Later, a third hard mask is formed to cover the first hard mask, the gate structure and the substrate, wherein the third hard mask prevents charges in the floating gate from flowing to the first hard mask. Finally, the third hard mask within the logic region is removed and only the third hard mask within the memory cell region remains.

By replacing the second hard mask covering the floating gate with the third hard mask, the electron charges can remain in the floating gate instead of being trapped by the first hard mask.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 10 depict a method of preventing charge loss in a floating gate according to a preferred embodiment of the present invention, wherein:

FIG. 1 depicts a top view of a memory cell region and a logic region;

FIG. 2 is a sectional view taken along line WW′ and line XX′ in FIG. 1;

FIG. 3 is a fabricating stage following FIG. 2;

FIG. 4 is a fabricating stage following FIG. 3;

FIG. 5 is a fabricating stage following FIG. 4;

FIG. 6 is a fabricating stage following FIG. 5;

FIG. 7 is a fabricating stage following FIG. 6;

FIG. 8 is a fabricating stage following FIG. 7;

FIG. 9 is a top view of a fabricating stage following FIG. 8; and

FIG. 10 is a sectional view taken along line YY′ and line ZZ′ in FIG. 9.

### DETAILED DESCRIPTION

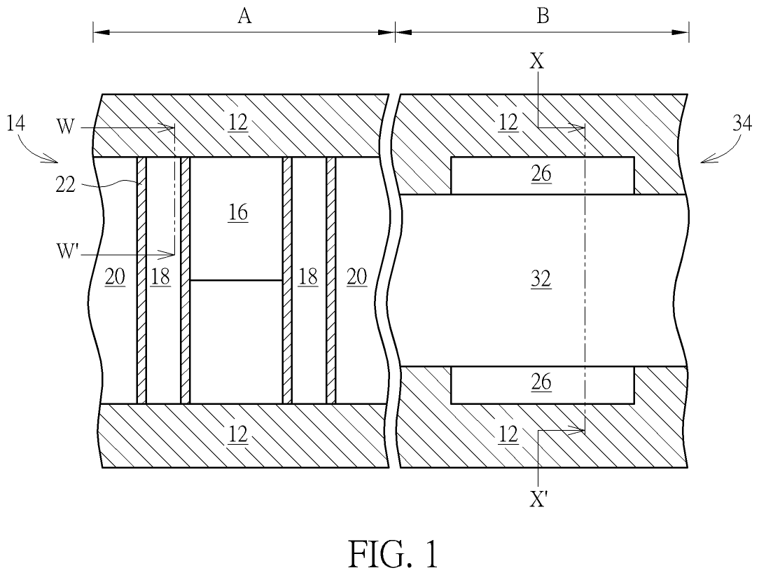

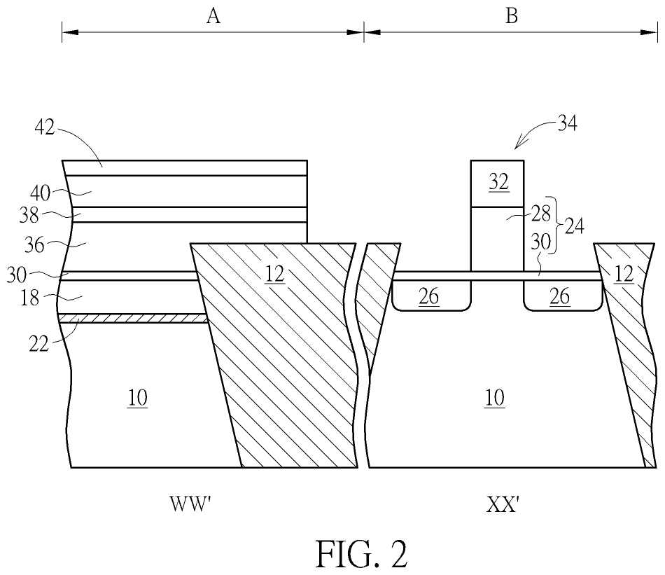

FIG. 1 to FIG. 10 depict a method of preventing charges loss in a floating gate according to a preferred embodiment of the present invention. FIG. 2 is a sectional view taken along line WW′ and line XX′ in FIG. 1.

As shown in FIG. 1 and FIG. 2, a substrate 10 is provided. The substrate 10 of the present invention is a bulk silicon substrate, a germanium substrate, a gallium arsenide substrate, a silicon germanium substrate, an indium phosphide substrate, a gallium nitride substrate, a silicon carbide substrate, or a silicon on insulator (SOI) substrate. The substrate 10 is divided into a memory cell region A and a logic region B. A shallow trench isolation (STI) 12 is embedded in the substrate 10 to define active regions in the memory cell region A and the logic region B. The shallow trench isolation 12 may include silicon oxide. A memory cell 14 such as a flash cell is disposed in the memory cell region A. The memory cell 14 includes an erase gate 16, two floating gates 18 and two word lines 20. The ease gate 16 is disposed on the substrate 10 within the memory cell region A. The two floating gates 18 are respectively disposed at two sides of the erase gate 16. The two word lines 20 are respectively disposed at one side of each of the floating gates 18. The floating gates 18, the erase gate 16, and the word lines 20 may be formed by polysilicon, metal or other conductive materials. A gate dielectric layer 22 is disposed between the floating gates 18, the erase gate 16, the word lines 20 and the substrate 10. The gate dielectric layer 22 may be silicon oxide, silicon oxynitride (SiON), silicon nitride (Si₃N₄), or any combination thereof. Although there is only one memory cell 14 shown in the figure, the number of the memory cells 14 can be adjusted based on different requirements.

A gate structure 24 is disposed in the logic region B. Two source/drain doped regions 26 are disposed in the substrate 10 at two sides of the gate structure 24. The gate structure 24 includes a gate 28 and a dielectric layer 30 disposed on the gate 28. The gate 28 may be formed by polysilicon, metal or other conductive materials. A cap layer 32 is disposed on the gate structure 24. The cap layer 32 may be silicon oxide, silicon nitride or the combination thereof.

The gate structure 24 and the two source/drain doped regions 26 forma MOS transistor 34. Although there is only one MOS transistor 34 shown in the figure, the number of the MOS transistors 34 can be adjusted based on different requirements. The gate 28 may be polysilicon. The dielectric layer 30 may be silicon oxide, silicon oxynitride (SiON), silicon nitride (Si₃N₄), or any combination thereof. The dielectric layer 30 is preferably silicon oxide. The dielectric layer 30 extends to the memory cell region A and covers the floating gate 18. Furthermore, a first hard mask 36, a second hard mask 38, a first sacrificial layer 40 and a second sacrificial layer 42 cover the dielectric layer 30 in the memory cell region A. The first hard mask 36 is preferably silicon nitride. The second hard mask 38 is preferably silicon oxide. The first sacrificial layer 40 is preferably silicon nitride. The second sacrificial layer 42 is preferably silicon oxide.

The first hard mask 36, the second hard mask 38, the first sacrificial layer 40 and the second sacrificial layer 42 are arranged from bottom to top. For the sake of clarity, the first hard mask 36, the second hard mask 38, the first sacrificial layer 40 and the second sacrificial layer 42 are omitted in FIG. 1.

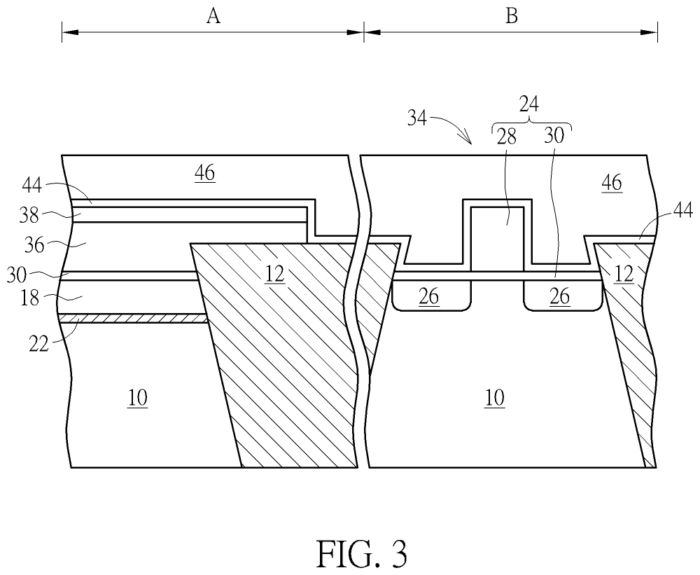

As shown in FIG. 3, the first sacrificial layer 40, the second sacrificial layer 42 and the cap layer 32 are removed entirely. Then, a first dielectric layer 44 is conformally formed to cover the second hard mask 42, the gate structure 24 and the substrate 10. A second dielectric layer 46 is formed to cover the first dielectric layer 44 and fills up the gaps between the first dielectric layer 44. The top surface of the second dielectric layer 46 is coplanar. The first dielectric layer 44 is preferably silicon nitride. The first dielectric layer 44 can serve as an etching stop layer. The second dielectric layer 46 is preferably silicon oxide.

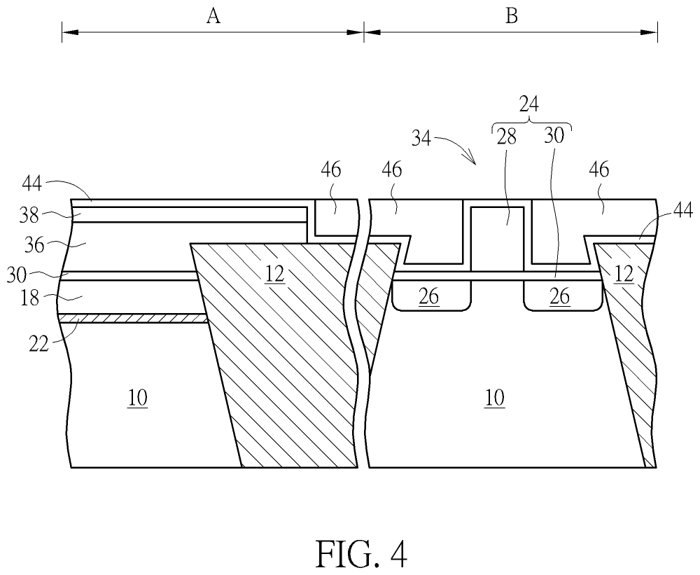

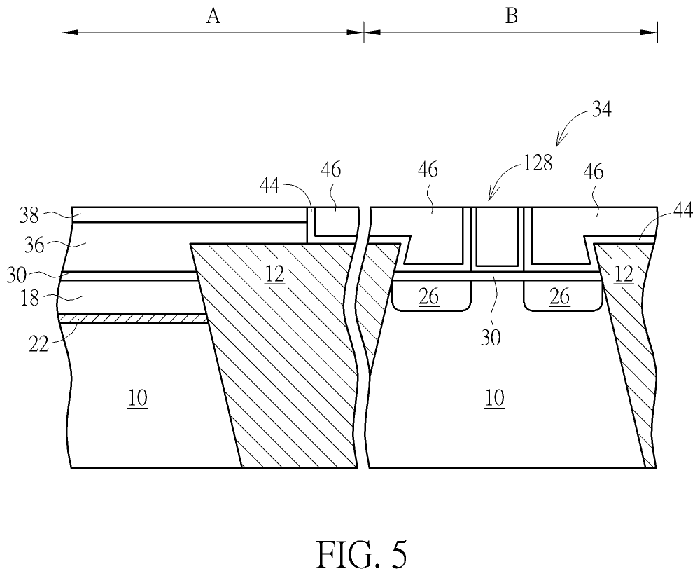

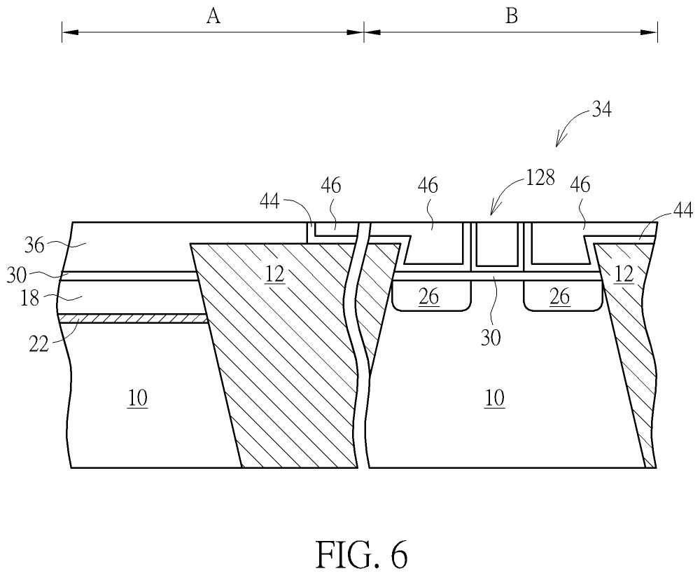

As shown in FIG. 4, part of the second dielectric layer 46 is removed by taking the first dielectric layer 44 as a stop layer. The second dielectric layer 46 can be removed by a chemical mechanical polish process. As shown in FIG. 5, part of the first dielectric layer 44 is removed to expose the gate 28 of the gate structure 24. The first dielectric layer 44 can be removed by another chemical mechanical polish process. Later, the gate 28 of the gate structure 24 is replaced by a metal structure 128. The metal structure 128 includes a metal electrode, a work function layer, and a barrier. As shown in FIG. 6, a planarization process such as a chemical mechanical polish process is performed to remove the second hard mask 38 partly by taking the first hard mask 36 as a stop layer. It is noteworthy that the second hard mask 38 in the memory cell region A is entirely removed in this step.

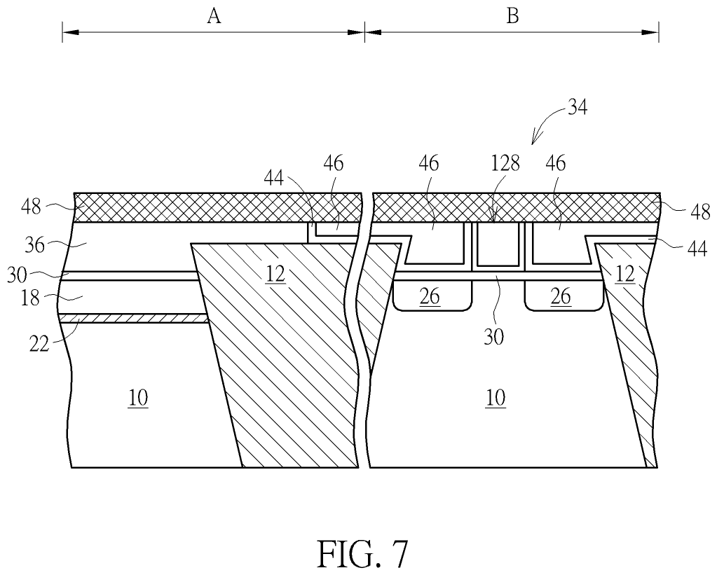

As shown in FIG. 7, a third hard mask 48 is formed to cover the memory cell region A and the logic region B. A thickness of the third hard mask 48 is smaller than twice the thickness of the second hard mask 38. According to a preferred embodiment of the present invention, the thickness of the second hard mask 38 equals the thickness of the third hard mask 48. Furthermore, the third hard mask 48 may be silicon oxide, silicon oxycarbonitride (SiOCN) or silicon oxynitride (SiON). The third hard mask 48 can prevent charges in the floating gates 18 from flowing to the first hard mask 36.

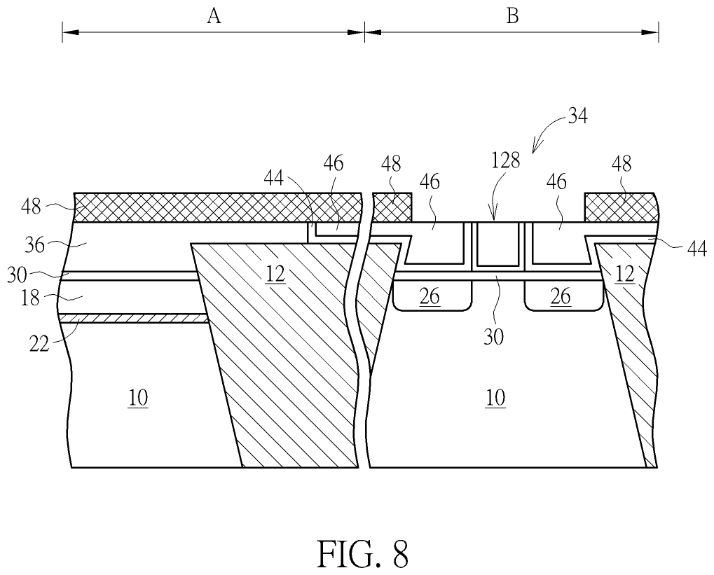

As shown in FIG. 8, a patterned photoresist (not shown) is formed to cover the memory cell region A, and expose the logic region B. Later, the third hard mask 48 in the logic region B is removed by taking the metal structure as a stop layer.

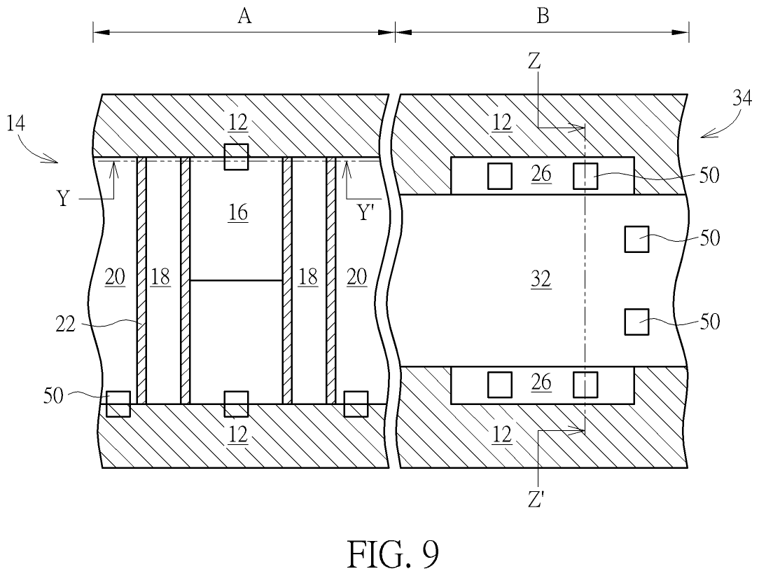

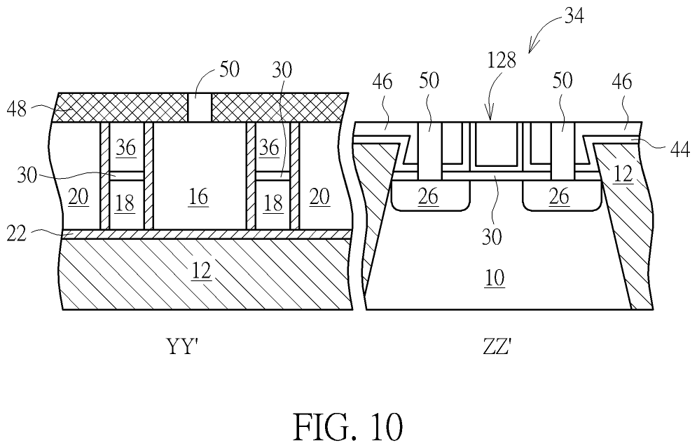

FIG. 9 is a top view showing a fabricating step continuing from FIG. 8. FIG. 10 is a section view taken along line YY′ and line ZZ′ in FIG. 9. For the sake of clarity, the third hard mask 48 is omitted in FIG. 9. As shown in FIG. 9 and FIG. 10, several contact plugs 50 are formed simultaneously in the memory cell region A, and the logic region B. Because the third hard mask 48 in the logic region B is removed, the total thickness of the first dielectric layer 44 and the second dielectric layer 46 are the same as in the conventional process. Therefore, the contact plugs 50 in the logic region B can be formed using the same operational parameters as in the conventional process. Contact plugs 50 in the memory cell region A respectively contact the erase gate 16 and the word lines 20. The contact plugs 50 in the logic region B contact the source/drain doped regions 26 and the gate structure 24 of the MOS transistor 34. At this point, the method of preventing charge loss in a floating gate is completed.

A conventional memory cell has a problem where the electrical charges stored in the floating gates are inclined to cross the dielectric layer and flow into the first hard mask. Eventually, the electrical charges originally in the floating gate are trapped in the first hard mask. Electron charges trapped in the first hard mask may elongate charge-discharge times of the memory cell. The present invention replaces the second hard mask originally on the first hard mask with the third hard mask. The third hard mask decreases the trapping ability of the first hard mask, and the electrical charges can be kept in the floating gates.

Those skilled in the art will readily observe that numerous modifications and alterations of the device and method may be made while retaining the teachings of the invention. Accordingly, the above disclosure should be construed as limited only by the metes and bounds of the appended claims.

1: A method of preventing charge loss from a floating gate, comprising:
providing a substrate comprising a memory cell region and a logic region, wherein the floating gate is disposed in the memory cell region and a gate structure is disposed within the logic region, a first hard mask covers the floating gate and a second hard mask covers the first hard mask;
performing a planarization process to remove entirely the second hard mask and expose the first hard mask;
forming a third hard mask to cover the first hard mask, the gate structure and the substrate, wherein the third hard mask prevents charges in the floating gate from flowing to the first hard mask; and
removing the third hard mask within the logic region while the third hard mask remains within the memory cell region.

2: The method of preventing charge loss from the floating gate of claim 1, wherein the first hard mask is silicon nitride and the second hard mask is silicon oxide.

3: The method of preventing charge loss from the floating gate of claim 1, wherein the third hard mask comprises silicon oxide, silicon oxycarbonitride (SiOCN) or silicon oxynitride (SiON).

4: The method of preventing charge loss from the floating gate of claim 1, wherein a thickness of the second hard mask equals a thickness of the third hard mask.

5: The method of preventing charge loss from the floating gate of claim 1, wherein a thickness of the third hard mask is smaller than twice a thickness of the second hard mask.

6: The method of preventing charge loss from the floating gate of claim 1, wherein an erase gate is disposed at a side of the floating gate, and after removing the third hard mask within the logic region, simultaneously forming contact plugs which respectively contact the gate structure and the erase gate.
